(19) United States
(12) Patent Application Publication
(10) Pub. No.: US 2026/0293227 A1
(43) Pub. Date: Sep. 24, 2026

(54) METHOD FOR MANUFACTURING SEMICONDUCTOR DEVICE AND SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Tomoyuki SAKUMA, Kanazawa Ishikawa (JP); Koji KIMURA, Nonoichi Ishikawa (JP)

(21) Appl. No.: 19/302,775

(22) Filed: Aug. 18, 2025

(30) Foreign Application Priority Data
Mar. 21, 2025 (JP) 2025-047038

(51) Int. Cl. H10D 62/10; H10D 8/00; H10D 8/01; H10D 30/01; H10D 30/63; H10D 64/27

(52) U.S. Cl. CPC H10D 62/107; H10D 8/045; H10D 8/411; H10D 30/025; H10D 30/63; H10D 64/513

(57) ABSTRACT

According to one embodiment, a method for manufacturing a semiconductor device includes preparing a structure body. The structure body includes a semiconductor layer, a first metal layer located on a part of the semiconductor layer, and a second metal layer located around the first metal layer along a first plane on another part of the semiconductor layer. The second metal layer includes aluminum. The method includes forming a first layer at a side surface of the second metal layer facing the first metal layer. The first layer does not substantially include aluminum. The method includes processing an upper surface of the semiconductor layer by wet etching. The method includes forming a semi-insulating layer in contact with the upper surface of the semiconductor layer. The semi-insulating layer is electrically connected with the first and second metal layers.

### CROSS-REFERENCE TO RELATED APPLICATIONS

This application is based upon and claims the benefit of priority from Japanese Patent Application No.2025-047038, filed on Mar. 21, 2025; the entire contents of which are incorporated herein by reference.

### FIELD

Embodiments of the invention relate to a method for manufacturing a semiconductor device and a semiconductor device.

### BACKGROUND

Semiconductor devices such as diodes, metal-oxide-semiconductor field-effect transistors (MOSFETs), and insulated gate bipolar transistors (IGBTs) are used in applications such as power conversion. It is desirable to make semiconductor devices so that short-circuits do not occur easily.

### BRIEF DESCRIPTION OF THE DRAWINGS

FIG. 1 is a plan view showing a semiconductor device according to a first embodiment;

FIG. 2 is a II-II cross-sectional view of FIG. 1;

FIGS. 3A and 3B are cross-sectional views showing a manufacturing method according to the first embodiment;

FIGS. 4A and 4B are cross-sectional views showing the manufacturing method according to the first embodiment;

FIGS. 5A and 5B are cross-sectional views showing the manufacturing method according to the first embodiment;

FIGS. 6A to 6C are cross-sectional views showing a manufacturing method according to a reference example;

FIGS. 7A and 7B are cross-sectional views showing a method for manufacturing a semiconductor device according to a first modification of the first embodiment;

FIGS. 8A and 8B are cross-sectional views showing the method for manufacturing the semiconductor device according to the first modification of the first embodiment;

FIGS. 9A and 9B are cross-sectional views showing a method for manufacturing a semiconductor device according to a second modification of the first embodiment;

FIG. 10 is a plan view showing a semiconductor device according to a second embodiment;

FIG. 11 is a XI-XI cross-sectional view of FIG. 10; and

FIG. 12 is a cross-sectional view showing a part of a semiconductor device according to a third embodiment.

### DETAILED DESCRIPTION

According to one embodiment, a method for manufacturing a semiconductor device includes preparing a structure body. The structure body includes a semiconductor layer, a first metal layer located on a part of the semiconductor layer, and a second metal layer located around the first metal layer along a first plane on another part of the semiconductor layer The first plane is perpendicular to a first direction from the semiconductor layer toward the first metal layer. The second metal layer includes aluminum. The method includes forming a first layer at a side surface of the second metal layer facing the first metal layer. The first layer does not substantially include aluminum. The method includes processing an upper surface of the semiconductor layer by wet etching. The method includes forming a semi-insulating layer in contact with the upper surface of the semiconductor layer. The semi-insulating layer is electrically connected with the first and second metal layers.

Embodiments of the invention will now be described with reference to the drawings. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. In the drawings and the specification of the application, components similar to those described thereinabove are marked with like reference numerals, and a detailed description is omitted as appropriate.

In the following descriptions and drawings, notations of n⁺, n⁻ and p⁺, p represent relative heights of impurity concentrations in conductivity types. That is, the notation with “+” shows a relatively higher impurity concentration than an impurity concentration for the notation without any of “+” and “-”. The notation with “-” shows a relatively lower impurity concentration than the impurity concentration for the notation without any of them.

The embodiments described below may be implemented by reversing the p-type and the n-type of the semiconductor regions.

### First embodiment

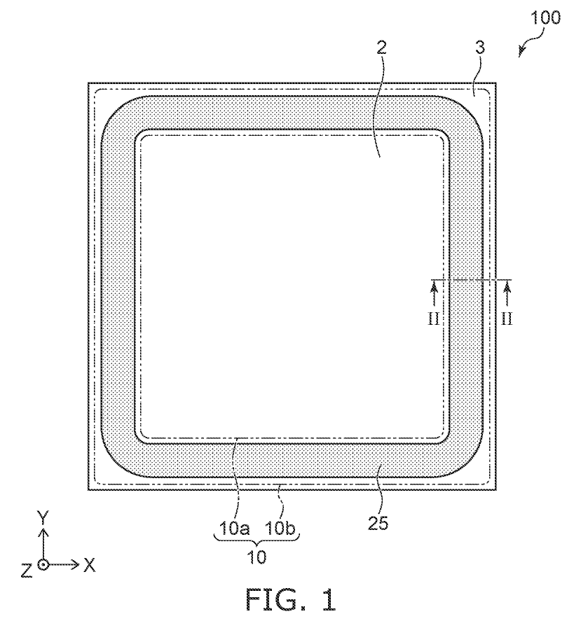

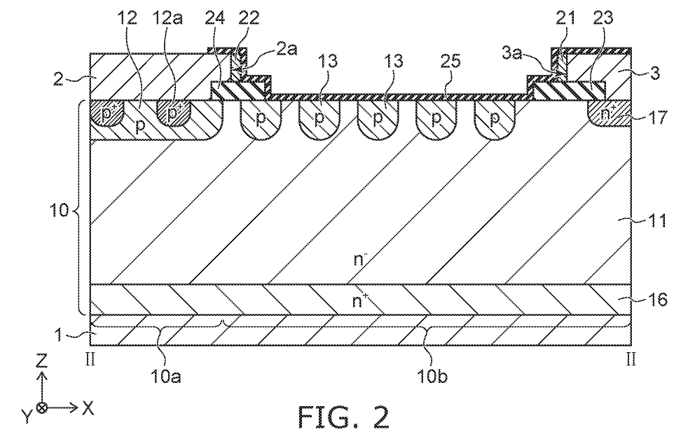

FIG. 1 is a plan view showing a semiconductor device according to a first embodiment. FIG. 2 is a II-II cross-sectional view of FIG. 1.

As shown in FIGS. 1 and 2, the semiconductor device 100 according to the first embodiment includes a lower electrode 1 (a first electrode), an upper electrode 2 (a second electrode), an equivalent-potential ring (EQPR) electrode 3 (a third electrode), a semiconductor layer 10, a first layer 21, a second layer 22, an insulating layer 23, an insulating layer 24, and a semi-insulating layer 25. The semi-insulating layer 25 that is formed on the EQPR electrode 3 is not illustrated in FIG. 1.

An XYZ orthogonal coordinate system is used in the description of embodiments. The direction from the lower electrode 1 toward the semiconductor layer 10 is referred to as a Z-direction (a first direction). Two mutually-orthogonal directions perpendicular to the Z-direction are referred to as a Y-direction and an X-direction. In the description, the direction from the lower electrode 1 toward the semiconductor layer 10 also is referred to as "up" or "above", and the opposite direction also is referred to as "down" or "below". These directions are based on the relative positional relationship between the lower electrode 1 and the semiconductor layer 10 and are independent of the direction of gravity.

As shown in FIG. 1, the upper electrode 2 and the EQPR electrode 3 are located at the upper surface of the semiconductor device 100 and are separated from each other. The EQPR electrode 3 is positioned around the upper electrode 2 along the X-Y plane (a first plane). For example, the EQPR electrode 3 is located along the outer perimeter of the semiconductor device 100.

As shown in FIG. 2, the lower electrode 1 is located at the lower surface of the semiconductor device 100. The semiconductor layer 10 is located on the lower electrode 1 between the lower electrode 1 and the upper electrode 2 and between the lower electrode 1 and the EQPR electrode 3.

As shown in FIGS. 1 and 2, the semiconductor layer 10 includes a first part 10a and a second part 10b. The first part 10a includes the central part of the semiconductor device 100 in the X-Y plane. The second part 10b is positioned around the first part 10a along the X-Y plane. The first part 10a is a cell part. The cell part is the region in which the current mainly flows when operating the semiconductor device 100. The second part 10b is a termination part. The termination part is a region in which a depletion layer spreads toward the outer perimeter of the semiconductor device 100 at the breakdown voltage of the semiconductor device 100. The upper electrode 2 is positioned on the first part 10a. The EQPR electrode 3 is positioned on the second part 10b.

The semiconductor device 100 is, for example, a diode. The semiconductor layer 10 includes an n⁻-type semiconductor region 11 (a first semiconductor region), a p-type semiconductor region 12 (a second semiconductor region), a p⁺-type contact region 12a, a p-type guard ring region 13 (a third semiconductor region), an n⁺-type contact region 16, and an n⁺-type EQPR region 17. The n-type is an example of a first conductivity type. The p-type is an example of a second conductivity type.

The n⁺-type contact region 16 is located on the lower electrode 1 and electrically connected with the lower electrode 1. The n⁻-type semiconductor region 11 is located on the n⁺-type contact region 16 and electrically connected with the lower electrode 1 via the n⁺-type contact region 16. The n-type impurity concentration in the n⁻-type semiconductor region 11 is less than the n-type impurity concentration in the n⁺-type contact region 16.

The p-type semiconductor region 12 is located on the n⁻-type semiconductor region 11 in the first part 10a. The p⁺-type contact region 12ais located on a portion of the p-type semiconductor region 12. The p-type impurity concentration in the p⁺-type contact region 12ais greater than the p-type impurity concentration in the p-type semiconductor region 12. The p-type semiconductor region 12 and the p⁺-type contact region 12a are electrically connected with the upper electrode 2.

The p-type guard ring region 13 is located around the p-type semiconductor region 12 along the X-Y plane. The p-type guard ring region 13 is positioned in the second part 10b. Multiple p-type guard ring regions 13 are arranged in the direction from the first part 10a toward the second part 10b. The multiple p-type guard ring regions 13 are separated from each other. The p-type impurity concentration in the p-type guard ring region 13 may be equal to or greater than the p-type impurity concentration in the p-type semiconductor region 12.

The n⁺-type EQPR region 17 is located around the multiple p-type guard ring regions 13 along the X-Y plane. The n⁺-type EQPR region 17 is separated from the p-type guard ring region 13 at the outermost perimeter. For example, the n⁺-type EQPR region 17 is located along the outer edge of the upper surface of the semiconductor layer 10 in the X-Y plane. The n-type impurity concentration in the n⁺-type EQPR region 17 is greater than the n-type impurity concentration in the n⁻-type semiconductor region 11.

The insulating layer 23 is located between a portion of the semiconductor layer 10 and the inner perimeter part of the EQPR electrode 3. The outer perimeter part of the EQPR electrode 3 contacts the n⁺-type EQPR region 17 and is electrically connected with the n⁺-type EQPR region 17. The insulating layer 24 is located between the outer perimeter part of the p-type semiconductor region 12 and the outer perimeter part of the upper electrode 2.

The EQPR electrode 3 includes a side surface 3a facing the upper electrode 2. The first layer 21 is located at the side surface 3a on the insulating layer 23. The upper electrode 2 includes a side surface 2a facing the EQPR electrode 3. The second layer 22 is located at the side surface 2a on the insulating layer 24.

The semi-insulating layer 25 covers the outer perimeter part of the semiconductor device 100. Specifically, the semi-insulating layer 25 contacts the outer perimeter part of the upper surface of the upper electrode 2, surfaces of the second layer 22, surfaces of the insulating layer 24, the upper surface of the semiconductor layer 10, surfaces of the insulating layer 23, surfaces of the first layer 21, and the upper surface of the EQPR electrode 3. The semi-insulating layer 25 is electrically connected with the upper electrode 2 and the EQPR electrode 3.

The semi-insulating layer 25 has an electrical resistivity such that a micro current can flow through the semi-insulating layer 25. When there is a potential difference between the upper electrode 2 and the EQPR electrode 3, a micro current flows between the upper electrode 2 and the EQPR electrode 3 via the semi-insulating layer 25. For example, the electrical resistivity of the semi-insulating layer 25 is greater than 1.0×10⁸ Ω⋅cm and less than 1.0×10¹³ Ω⋅cm. The electrical resistivity of the semi-insulating layer 25 may be less than 1.0×10¹² Ω⋅cm, or less than 1.0×10¹¹ Ω⋅cm.

Operations of the semiconductor device 100 will now be described. When a voltage that is positive with respect to the lower electrode 1 is applied to the upper electrode 2, a forward voltage is applied to a diode made of the n⁻-type semiconductor region 11 and the p-type semiconductor region 12. A current flows from the p-type semiconductor region 12 toward the n⁻-type semiconductor region 11; and the semiconductor device 100 is set to an on-state. Subsequently, when a voltage that is positive with respect to the upper electrode 2 is applied to the lower electrode 1, the flow of the current stops; and the semiconductor device 100 is set to an off-state. A reverse voltage is applied to the diode; and a depletion layer spreads from the p-n junction between the n⁻-type semiconductor region 11 and the p-type semiconductor region 12. A depletion layer also spreads in the second part 10bfrom the p-n junction between the n⁻-type semiconductor region 11 and the p-type guard ring region 13.

At the outer edge vicinity of the semiconductor device 100, the spreading of the depletion layer is suppressed by the n⁺-type EQPR region 17. If the depletion layer reaches the outer edge of the semiconductor device 100, a leakage current flows between the lower electrode 1 and the upper electrode 2 via the side surface of the semiconductor device 100. By suppressing the spreading of the depletion layer with the n⁺-type EQPR region 17, the occurrence of the leakage current can be suppressed.

When the semiconductor device 100 is in the off-state, the potentials of the n⁺-type EQPR region 17 and the EQPR electrode 3 are substantially equal to the potential of the lower electrode 1. A micro current flows from the EQPR electrode 3 toward the upper electrode 2 via the semi-insulating layer 25 due to the potential difference between the upper electrode 2 and the EQPR electrode 3. A gradient of the potential is generated in the semi-insulating layer 25 by the flow of the current. The semi-insulating layer 25 is electrically connected with the p-type guard ring regions 13. The potential of each p-type guard ring region 13 is determined according to the position of the p-type guard ring region 13. By including the semi-insulating layer 25, the fluctuation of the potential of each p-type guard ring region 13 when the semiconductor device 100 is in the off-state can be reduced. As a result, the spreading of the depletion layer in the second part 10b can be stabilized, and the breakdown voltage of the semiconductor device 100 can be stabilized.

Examples of the materials of the components will now be described. The lower electrode 1, the upper electrode 2, and the EQPR electrode 3 include aluminum. In addition to aluminum, the lower electrode 1, the upper electrode 2, and the EQPR electrode 3 may include copper or silicon. In addition to a layer that includes aluminum, the lower electrode 1, the upper electrode 2, and the EQPR electrode 3 may include a barrier layer such as a titanium layer, a titanium nitride layer, etc., at the interfaces with the semiconductor layer 10.

The semiconductor layer 10 includes silicon, silicon carbide, gallium nitride, or gallium arsenide as a semiconductor material. When silicon is used as the semiconductor material, arsenic, phosphorus, or antimony can be used as an n-type impurity. Boron can be used as a p-type impurity.

The first layer 21 and the second layer 22 substantially do not include aluminum. Herein, "substantially not include" refers to not adding intentionally. For example, the first layer 21 and the second layer 22 can be considered to substantially not include aluminum if the aluminum content ratios in the first and second layers 21 and 22 are not more than 0.1 mass%. Energy dispersive X-ray spectrometry (EDX) of the cross section can be used to analyze the content ratio.

For example, the first layer 21 and the second layer 22 include a metal material, a compound of a semiconductor material, or a compound of a metal material. The first layer 21 and the second layer 22 may be conductive or insulative. As an example, the first layer 21 and the second layer 22 include at least one selected from the group consisting of tungsten, molybdenum, titanium nitride, silicon nitride, and tantalum nitride.

The insulating layers 23 and 24 include insulating materials such as silicon oxide, silicon nitride, silicon oxynitride, etc. The semi-insulating layer 25 includes semi-insulating silicon nitride (SInSiN). Or, the semi-insulating layer 25 may include semi-insulating polysilicon (SIPOS).

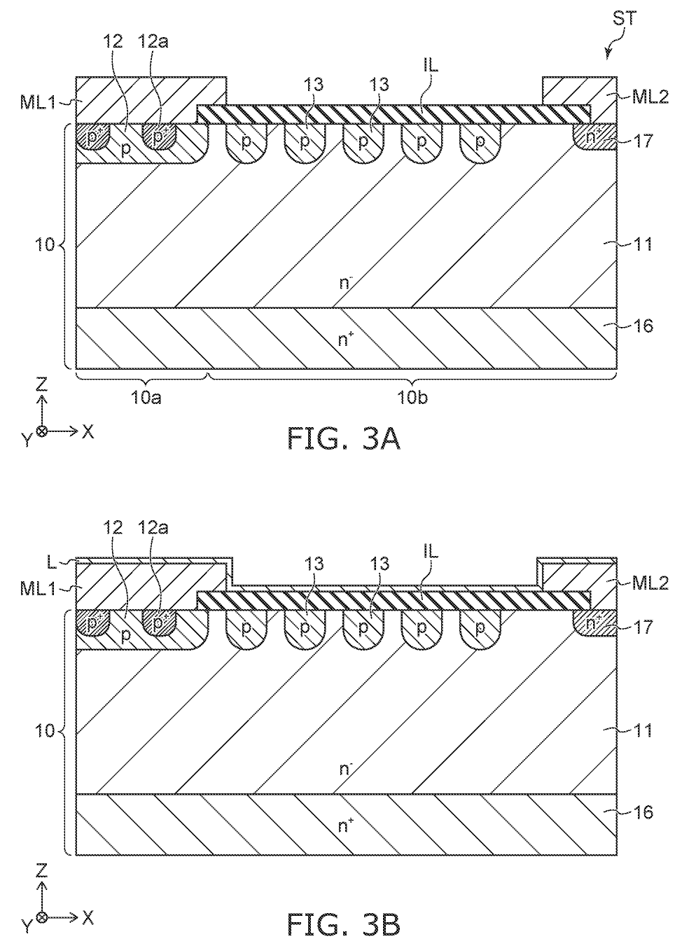

FIGS. 3A, 3B, 4A, 4B, 5A, and 5B are cross-sectional views showing the manufacturing method according to the first embodiment.

First, a structure body ST shown in FIG. 3A is prepared by known methods. In the structure body ST, the semiconductor layer 10 includes the n⁻-type semiconductor region 11, the p-type semiconductor region 12, the p⁺-type contact region 12a, the p-type guard ring region 13, the n⁺-type contact region 16, and the n⁺-type EQPR region 17. A first metal layer ML1 is located on the p-type semiconductor region 12 and the p⁺-type contact region 12a. An insulating layer IL is located on the multiple p-type guard ring regions 13. A second metal layer ML2 is located around the first metal layer ML1 and the insulating layer IL along the X-Y plane. The second metal layer ML2 is positioned on the n⁺-type EQPR region 17. The first metal layer ML1 and the second metal layer ML2 correspond to the upper electrode 2 and the EQPR electrode 3 shown in FIGS. 1 and 2.

As shown in FIG. 3B, a layer L is formed along surfaces of the first metal layer ML1, the upper surface of the insulating layer IL, and surfaces of the second metal layer ML2. The layer L includes at least one selected from the group consisting of tungsten, molybdenum, titanium nitride, silicon nitride, and tantalum nitride. The layer L can be formed by sputtering when the layer L includes tungsten, molybdenum, titanium nitride, or tantalum nitride. The layer L can be formed by chemical vapor deposition (CVD) when the layer L includes silicon nitride.

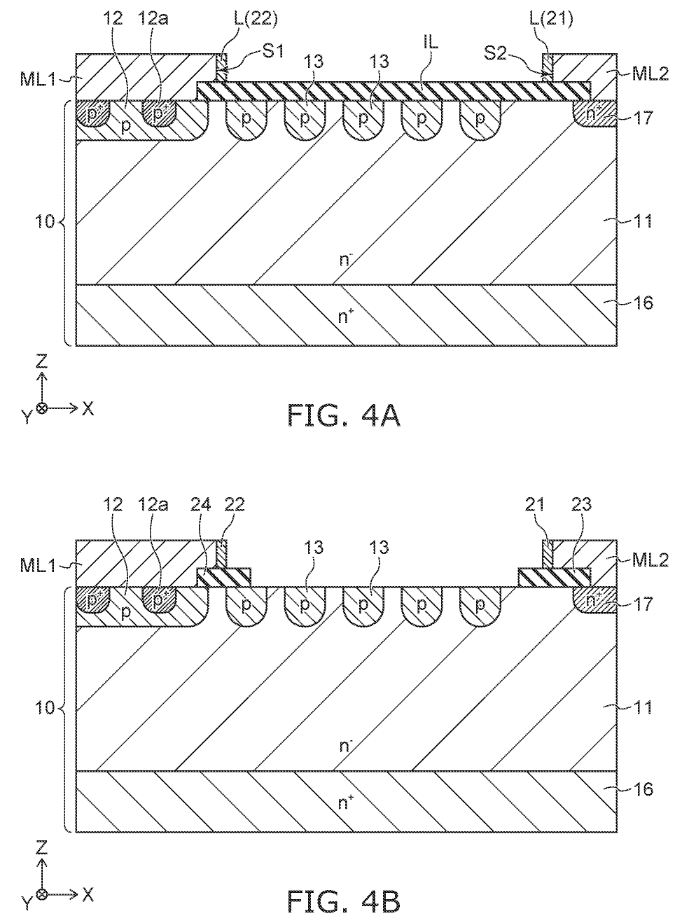

A portion of the layer L is removed by reactive ion etching (RIE). As a result, as shown in FIG. 4A, the layer L that is formed on the upper surface of the first metal layer ML1, the upper surface of the insulating layer IL, and the upper surface of the second metal layer ML2 is removed. RIE is anisotropic etching that removes an object with ions incident along the Z-direction. The Z-direction thickness of the layer L that is formed at a side surface S1 of the first metal layer ML1 and a side surface S2 of the second metal layer ML2 is greater than the Z-direction thickness of the other parts of the layer L. Therefore, the layer L remains at the side surfaces S1 and S2 after the RIE. The layer L at the side surface S1 and the layer L at the side surface S2 correspond respectively to the second layer 22 and the first layer 21 shown in FIG. 2.

A portion of the insulating layer IL is removed by photolithography and RIE. As a result, as shown in FIG. 4B, the insulating layer IL is divided into the insulating layers 23 and 24. Each p-type guard ring region 13 is exposed. The exposed upper surface of the semiconductor layer 10 is processed by wet etching. A chemical liquid that includes fluorine is used in the wet etching. The wet etching removes an oxide thin film formed at the upper surface of the semiconductor layer 10. For example, diluted hydrofluoric acid or buffered hydrofluoric acid can be used as the chemical liquid.

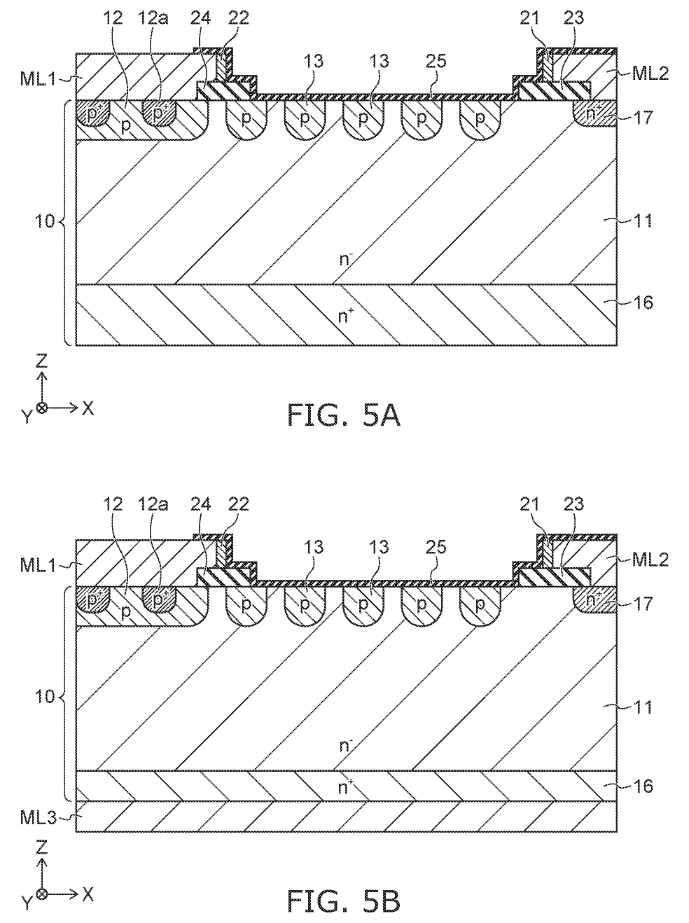

As shown in FIG. 5A, the semi-insulating layer 25 is formed by CVD at the upper surface of the outer perimeter part of the first metal layer ML1, surfaces of the second layer 22, surfaces of the insulating layer 24, the upper surface of the semiconductor layer 10, surfaces of the insulating layer 23, surfaces of the first layer 21, and the upper surface of the second metal layer ML2. By pre-processing the upper surface of the semiconductor layer 10 by wet etching, the p-type guard ring region 13 and the semi-insulating layer 25 can be electrically connected more reliably.

The lower surface of the semiconductor layer 10 is polished until the semiconductor layer 10 has a prescribed thickness. As shown in FIG. 5B, a third metal layer ML3 is formed on the polished lower surface by sputtering. The third metal layer ML3 corresponds to the lower electrode 1 shown in FIG. 2. The semiconductor device 100 according to the first embodiment is manufactured by the processing described above.

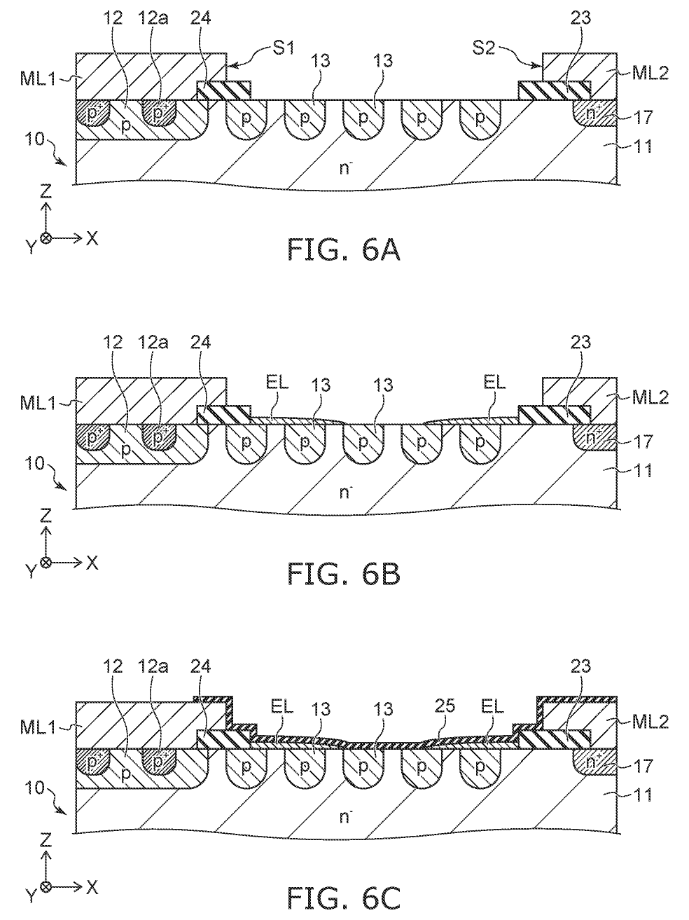

FIGS. 6A to 6C are cross-sectional views showing a manufacturing method according to a reference example.

According to the manufacturing method according to the reference example as shown in FIG. 6A, the layer L is not formed at the side surface S1 of the first metal layer ML1 and the side surface S2 of the second metal layer ML2. In this state, the upper surface of the semiconductor layer 10 is processed by wet etching.

At this time, the chemical liquid that includes hydrofluoric acid reacts with the aluminum included in the first and second metal layers ML1 and ML2; and the aluminum elutes from the first and second metal layers ML1 and ML2. A portion of the eluted aluminum is deposited on the upper surface of the semiconductor layer 10 and forms an elution layer EL as shown in FIG. 6B. Subsequently, the semi-insulating layer 25 is formed as shown in FIG. 6C.

Advantages of the manufacturing method according to the first embodiment will now be described.

When the semiconductor device is used in a state in which the elution layer EL shown in FIG. 6C is present, the aluminum included in the elution layer EL may agglomerate and move along the electric field direction. A short-circuit occurs between the lower electrode 1 and the upper electrode 2 when the upper electrode 2 and the EQPR electrode 3 are electrically connected by the aluminum of the elution layer EL.

For this problem, when the wet etching is performed in the manufacturing method according to the first embodiment, the first layer 21 is formed on at least the side surface S2 of the second metal layer ML2. The first layer 21 substantially does not include aluminum. Therefore, aluminum does not elute from the first layer 21 even when the first layer 21 is exposed to the chemical liquid used in the wet etching. By forming the first layer 21, the elution of aluminum from the side surface S2 can be suppressed. As a result, short-circuits between the lower electrode 1 and the upper electrode 2 due to the eluted aluminum can be suppressed.

The EQPR electrode 3 is located around the upper electrode 2; and the surface area of the inner perimeter side surface of the EQPR electrode 3 is greater than the surface area of the outer perimeter side surface of the upper electrode 2. Therefore, if the first layer 21 is formed on at least the side surface S2 of the second metal layer ML2, the amount of aluminum eluted by the wet etching can be effectively reduced.

According to the first embodiment, a method for manufacturing a semiconductor device in which short-circuits can be suppressed and a semiconductor device in which short-circuits can be suppressed are provided.

More favorably, as shown in FIG. 4A, the second layer 22 is formed at the side surface S1 of the first metal layer ML1. By forming the second layer 22 at the side surface S1, the elution of aluminum from the side surface S1 also can be suppressed. As a result, short-circuits between the lower electrode 1 and the upper electrode 2 due to eluted aluminum can be more reliably suppressed.

It is favorable for the first and second layers 21 and 22 to be conductive. When the first layer 21 and the second layer 22 are conductive, the side surface S1 of the first metal layer ML1 is electrically connected with the semi-insulating layer 25 via the second layer 22. The side surface S2 of the second metal layer ML2 is electrically connected with the semi-insulating layer 25 via the first layer 21. As a result, the first metal layer ML1 and the second metal layer ML2 are electrically connected more reliably with the semi-insulating layer 25. As a result, spreading of the depletion layer in the second part 10b can be more stable.

According to the semiconductor device 100 according to the embodiment, the first layer 21 is located at the side surface of the EQPR electrode 3. It is favorable for the first layer 21 to be conductive. The conductive first layer 21 is located at the side surface of the EQPR electrode 3 and substantially functions as a portion of the EQPR electrode 3. By including the conductive first layer 21, the electrical resistance of the EQPR electrode 3 can be less than when the first layer 21 is not included. As a result, the EQPR electrode 3 is electrically connected more reliably with the semi-insulating layer 25.

Favorably, in the semiconductor device 100, the second layer 22 that is conductive is located at the side surface of the upper electrode 2. The conductive second layer 22 substantially functions as a portion of the upper electrode 2. By including the conductive second layer 22, the electrical resistance of the upper electrode 2 can be less than when the second layer 22 is not included. As a result, the upper electrode 2 is electrically connected more reliably with the semi-insulating layer 25.

### First modification

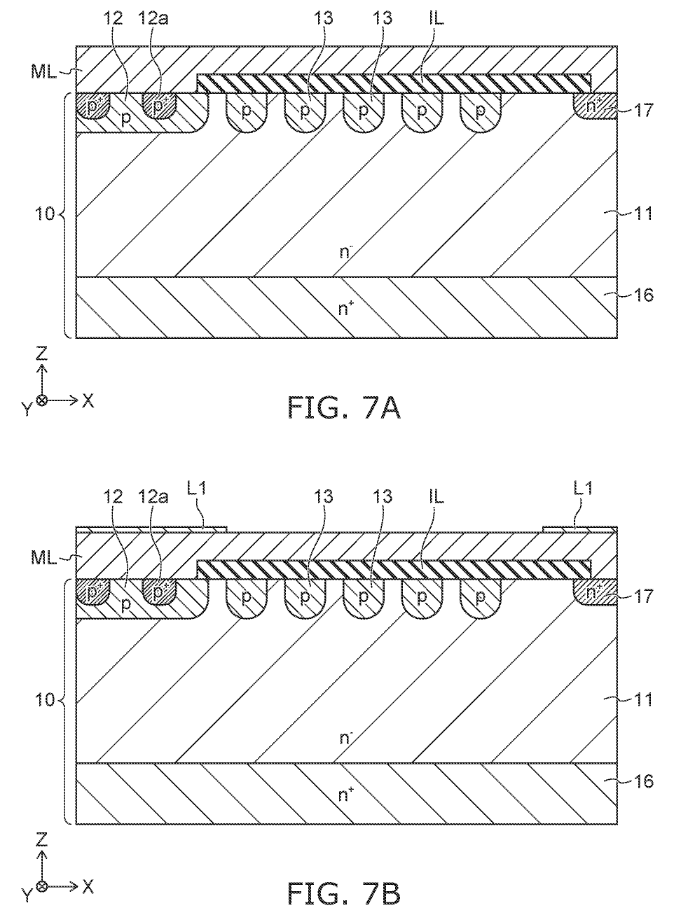

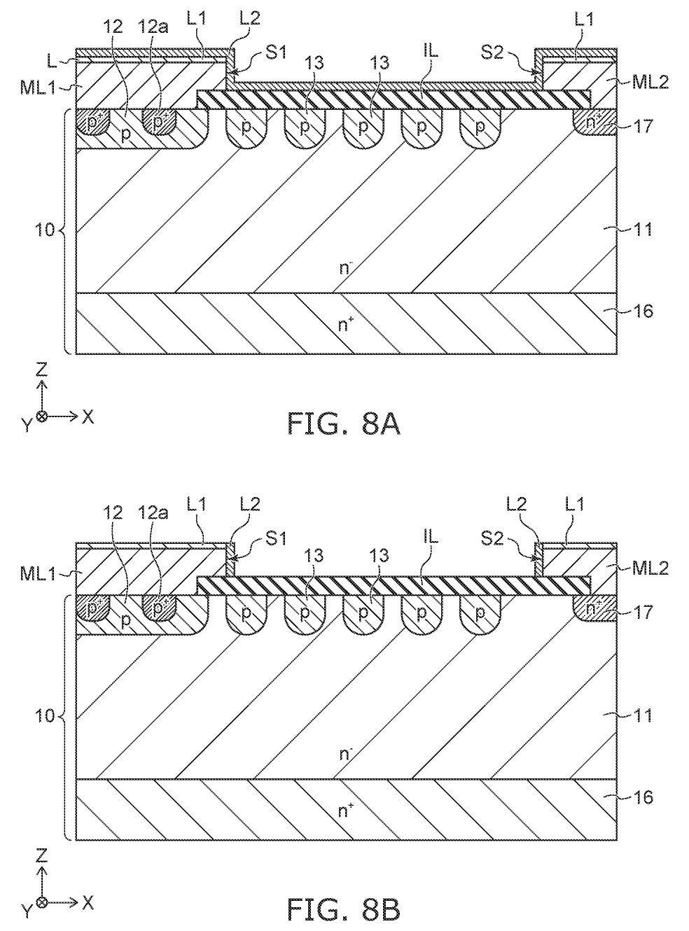

FIGS. 7A, 7B, 8A, and 8B are cross-sectional views showing a method for manufacturing a semiconductor device according to a first modification of the first embodiment.

First, as shown in FIG. 7A, a structure body in which the insulating layer IL and a metal layer ML are formed on the semiconductor layer 10 is prepared. The metal layer ML covers the upper surface of the semiconductor layer 10 and surfaces of the insulating layer IL.

A layer L1 is formed on the metal layer ML. The layer L1 includes at least one selected from the group consisting of tungsten, molybdenum, titanium nitride, silicon nitride, and tantalum nitride. As shown in FIG. 7B, a portion of the layer L1 is removed by photolithography and RIE. The layer L1 remains on the portion of the metal layer ML at which the upper electrode 2 and the EQPR electrode 3 will be formed.

A portion of the metal layer ML is removed by photolithography and RIE. As a result, the metal layer ML is divided into the first and second metal layers ML1 and ML2. As shown in FIG. 8A, a layer L2 is formed at surfaces of the layer L1, the side surface S1 of the first metal layer ML1, a surface of the insulating layer IL, and the side surface S2 of the second metal layer ML2. The layer L2 includes at least one selected from the group consisting of tungsten, molybdenum, titanium nitride, silicon nitride, and tantalum nitride. The material of the layer L2 may be the same as or different from the material of the layer L1.

A portion of the layer L2 is removed by RIE. The Z-direction thickness of the layer L2 formed at the side surfaces S1 and S2 is greater than the Z-direction thickness of the other portions of the layer L2. Therefore, as shown in FIG. 8B, the layer L2 remains at the side surfaces S1 and S2. The layer L1 that was covered with the layer L2 also remains.

Then, processes similar to the processes shown in FIG. 4B and subsequent drawings are performed. Specifically, a portion of the insulating layer IL is removed, the semi-insulating layer 25 is formed, and the third metal layer ML3 is formed. The semiconductor device 100 is manufactured by the processes described above.

According to the first modification, similarly to the first embodiment above, the elution of aluminum from the first and second metal layers ML1 and ML2 is suppressed.

According to the manufacturing method according to the first modification, the upper surface of the first metal layer ML1 and the upper surface of the second metal layer ML2 are covered with the layer L1; and the side surface S1 of the first metal layer ML1 and the side surface S2 of the second metal layer ML2 are covered with the layer L2. The layer L1 and the layer L2 that are formed at the surfaces of the EQPR electrode 3 correspond to the first layer 21 shown in FIG. 2. The layer L1 and the layer L2 that are formed at the surfaces of the upper electrode 2 correspond to the second layer 22. In other words, according to the manufacturing method according to the first modification, compared to the structure shown in FIG. 2, the first layer 21 also is formed at the upper surface of the EQPR electrode 3; and the second layer 22 also is formed at the upper surface of the upper electrode 2. In such a case, at least one layer of the layers L1 and L2 is conductive in order to electrically connect the first metal layer ML1 and the second metal layer ML2 with the semi-insulating layer 25. Favorably, both the layers L1 and L2 are conductive.

### Second modification

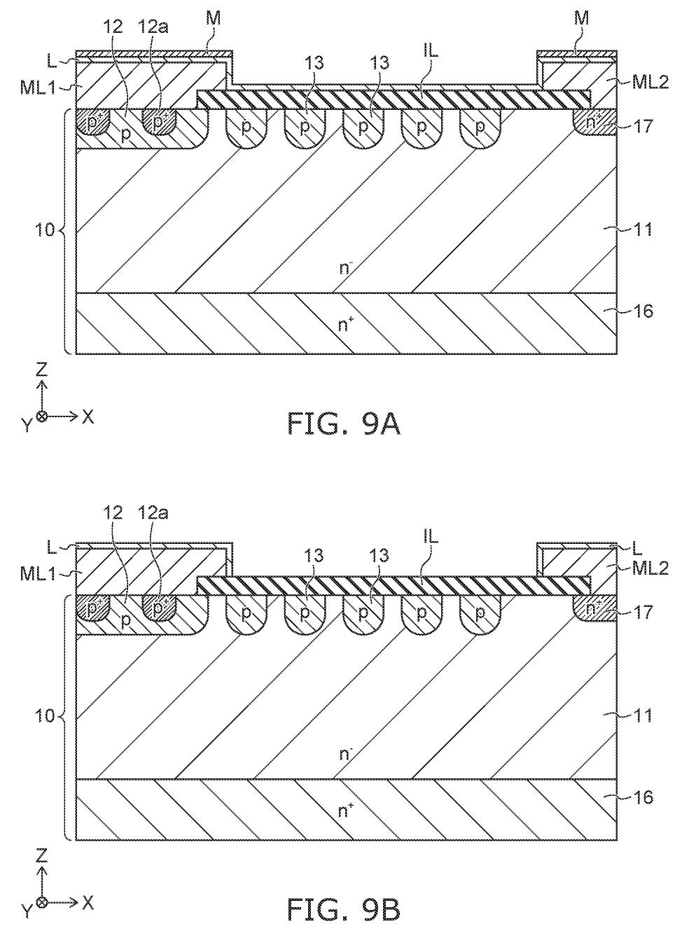

FIGS. 9A and 9B are cross-sectional views showing a method for manufacturing a semiconductor device according to a second modification of the first embodiment.

According to the manufacturing method according to the second modification, first, the layer L is formed by performing the process shown in FIG. 3B. Then, a mask M is formed on the first metal layer ML1 and on the second metal layer ML2 as shown in FIG. 9A by photolithography and RIE. The mask M may be a photoresist.

As shown in FIG. 9B, the layer L that is formed on the insulating layer IL is removed by RIE using the mask M. The mask M is removed. Then, processes similar to the processes shown in FIG. 4B and subsequent drawings are performed. Specifically, a portion of the insulating layer IL is removed, wet etching is performed, the semi-insulating layer 25 is formed, and the third metal layer ML3 is formed.

According to the second modification, similarly to the first embodiment and the first modification of the first embodiment, the elution of aluminum from the first and second metal layers ML1 and ML2 is suppressed.

According to the manufacturing method according to the second modification, similarly to the first modification, surfaces of the first metal layer ML1 and surfaces of the second metal layer ML2 are covered with the layer L. Therefore, the layer L is conductive in order to electrically connect the first metal layer ML1 and the second metal layer ML2 with the semi-insulating layer 25.

### Second embodiment

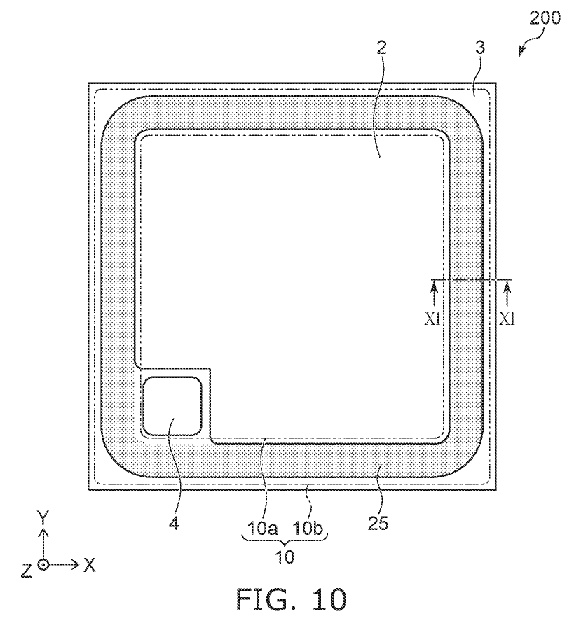

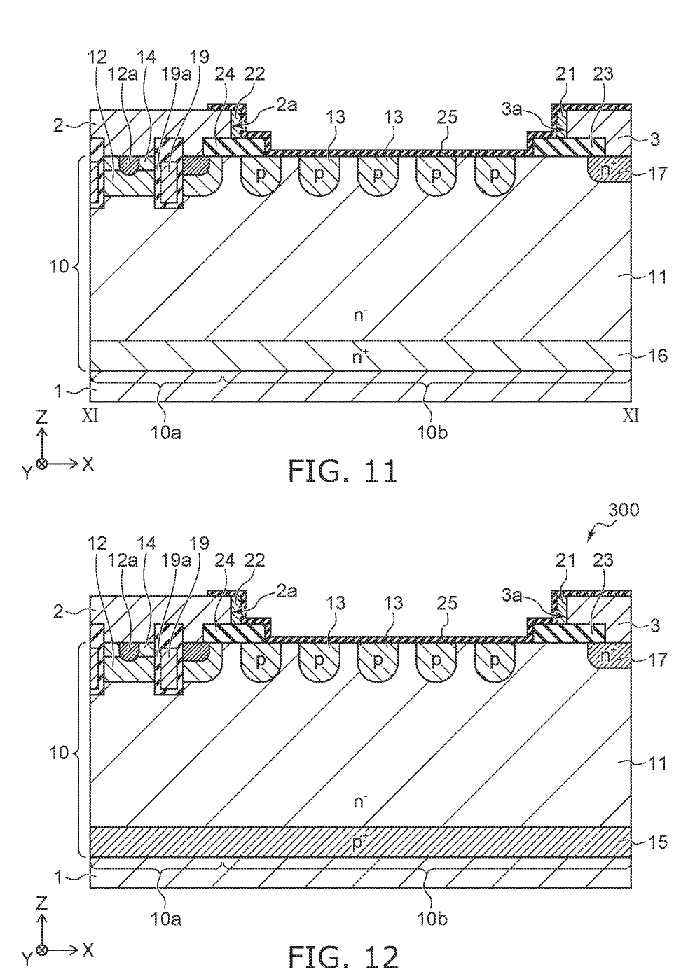

FIG. 10 is a plan view showing a semiconductor device according to a second embodiment. FIG. 11 is a XI-XI cross-sectional view of FIG. 10. The semi-insulating layer 25 that is formed on the EQPR electrode 3 is not illustrated in FIG. 10.

The semiconductor device 200 according to the second embodiment is a MOSFET. As shown in FIG. 10, compared to the semiconductor device 100 according to the first embodiment, the semiconductor device 200 further includes a gate pad 4. As shown in FIG. 11, the semiconductor layer 10 further includes an n⁺-type semiconductor region 14 (a fourth semiconductor region) and a gate electrode 19.

As shown in FIG. 10, the upper electrode 2 and the gate pad 4 are separated from each other at the upper surface of the semiconductor device 200 and are electrically isolated from each other. The gate pad 4 is positioned on the first part 10a. The EQPR electrode 3 and the semi-insulating layer 25 are located around the upper electrode 2 and the gate pad 4 along the X-Y plane.

As shown in FIG. 11, the n⁺-type semiconductor region 14 is located on the p-type semiconductor region 12. The gate electrode 19 faces the p-type semiconductor region 12 via a gate insulating layer 19a.

In the example shown in FIG. 11, the p-type semiconductor region 12 and the gate electrode 19 are alternately arranged in the X-direction. A pair of n⁺-type semiconductor regions 14 separated from each other in the X-direction is located on one p-type semiconductor region 12. The p⁺-type contact region 12ais located between a pair of n⁺-type semiconductor regions 14. Each p-type semiconductor region 12, each p⁺-type contact region 12a, each n⁺-type semiconductor region 14, and each gate electrode 19 extend in the Y-direction.

The gate electrode 19 includes a semiconductor material such as polysilicon, etc. A p-type impurity or an n-type impurity may be added to the gate electrode 19 to reduce the electrical resistivity of the gate electrode 19. The gate insulating layer 19aincludes an insulating material such as silicon oxide, silicon nitride, silicon oxynitride, etc.

The other configurations of the semiconductor device 200 may be similar to those of the semiconductor device 100. For example, the multiple p-type guard ring regions 13 are located in the second part 10b. The first layer 21, the second layer 22, the insulating layer 23, the insulating layer 24, and the semi-insulating layer 25 are located on the second part 10b.

In the semiconductor device 200, the lower electrode 1 functions as a drain electrode. The upper electrode 2 functions as a source electrode. A voltage that is not less than a threshold is applied to the gate electrode 19 in a state in which a voltage that is positive with respect to the upper electrode 2 is applied to the lower electrode 1. As a result, a channel is formed in the p-type semiconductor region 12. Electrons flow from the n⁺-type semiconductor region 14 to the n⁻-type semiconductor region 11 via the channel; and the semiconductor device 200 is set to an on-state. Subsequently, when the voltage applied to the gate electrode 19 drops below the threshold, the channel in the p-type semiconductor region 12 disappears, and the semiconductor device 200 is switched to an off-state. When the semiconductor device 200 is switched to the off-state, a depletion layer spreads from the p-n junction between the n⁻-type semiconductor region 11 and the p-type semiconductor region 12 and from the p-n junction between the n⁻-type semiconductor region 11 and the p-type guard ring region 13.

The processes shown in FIGS. 3A to 5B are applicable to the method for manufacturing the semiconductor device 200. For example, initially, the structure body ST is prepared similarly to the example shown in FIG. 3A. In the structure body ST, the semiconductor layer 10 includes the n⁻-type semiconductor region 11, the p-type semiconductor region 12, the p⁺-type contact region 12a, the p-type guard ring region 13, the n⁺-type semiconductor region 14, the n⁺-type contact region 16, the n⁺-type EQPR region 17, and the gate electrode 19. Subsequently, the formation of the layer L, the removal of a portion of the layer L, the removal of a portion of the insulating layer IL, the wet etching, the formation of the semi-insulating layer 25, and the formation of the third metal layer ML3 are performed.

According to the method for manufacturing the semiconductor device 200 according to the second embodiment, similarly to the first embodiment, the first layer 21 is formed at the side surface S2 of the second metal layer ML2 when the wet etching is performed. As a result, the elution of aluminum from the side surface S2 can be suppressed. As a result, in the semiconductor device 200, short-circuits between the lower electrode 1 and the upper electrode 2 due to eluted aluminum can be suppressed.

### Third embodiment

FIG. 12 is a cross-sectional view showing a part of a semiconductor device according to a third embodiment.

The semiconductor device 300 according to the third embodiment is an IGBT. In the semiconductor device 300 as shown in FIG. 12, compared to the semiconductor device 200, the semiconductor layer 10 includes a p⁺-type collector region 15 instead of the n⁺-type contact region 16. The p⁺-type collector region 15 is located between the lower electrode 1 and the n⁻-type semiconductor region 11. The other configurations of the semiconductor device 300 may be similar to those of the semiconductor device 200.

In the semiconductor device 300, the lower electrode 1 functions as a collector electrode. The upper electrode 2 functions as an emitter electrode. A voltage that is not less than a threshold is applied to the gate electrode 19 in a state in which a voltage that is positive with respect to the upper electrode 2 is applied to the lower electrode 1. As a result, a channel (an inversion layer) is formed in the p-type semiconductor region 12. Electrons flow from the n⁺-type semiconductor region 14 toward the n⁻-type semiconductor region 11 via the channel; and holes flow from the p⁺-type collector region 15 toward the n⁻-type semiconductor region 11. The density of carriers accumulated in the n⁻-type semiconductor region 11 increases, and conductivity modulation occurs. As a result, the electrical resistance in the n⁻-type semiconductor region 11 is greatly reduced, and the semiconductor device 300 is set to an on-state. Subsequently, when the voltage applied to the gate electrode 19 drops below the threshold, the channel in the p-type semiconductor region 12 disappears, and the semiconductor device 300 is switched to an off-state.

The processes shown in FIGS. 3A to 5B are applicable to the method for manufacturing the semiconductor device 300. For example, initially, the structure body ST is prepared similarly to the example shown in FIG. 3A. In the structure body ST, the semiconductor layer 10 includes the n⁻-type semiconductor region 11, the p-type semiconductor region 12, the p⁺-type contact region 12a, the p-type guard ring region 13, the n⁺-type semiconductor region 14, the n⁺-type contact region 16, the n⁺-type EQPR region 17, and the gate electrode 19. Subsequently, the formation of the layer L, the removal of a portion of the layer L, the removal of a portion of the insulating layer IL, the wet etching, the formation of the semi-insulating layer 25, and the formation of the third metal layer ML3 are performed.

According to the method for manufacturing the semiconductor device 300 according to the third embodiment, similarly to the first embodiment, the first layer 21 is formed at the side surface S2 of the second metal layer ML2 when the wet etching is performed. As a result, the elution of aluminum from the side surface S2 can be suppressed. As a result, in the semiconductor device 300, short-circuits between the lower electrode 1 and the upper electrode 2 due to eluted aluminum can be suppressed.

The embodiments of the invention include the following features.

Feature 1

A method for manufacturing a semiconductor device, the method including:

preparing a structure body, the structure body including

a semiconductor layer,

a first metal layer located on a part of the semiconductor layer, and

a second metal layer located around the first metal layer along a first plane on another part of the semiconductor layer, the first plane being perpendicular to a first direction from the semiconductor layer toward the first metal layer, the second metal layer including aluminum;

forming a first layer at a side surface of the second metal layer facing the first metal layer, the first layer substantially not including aluminum;

processing an upper surface of the semiconductor layer by wet etching; and

forming a semi-insulating layer in contact with the upper surface of the semiconductor layer, the semi-insulating layer being electrically connected with the first and second metal layers.

Feature 2

The method according to feature 1, in which

the first layer is conductive and is electrically connected with the semi-insulating layer.

Feature 3

The method according to feature 2, in which

the first layer also is formed at the upper surface of the second metal layer.

Feature 4

The method according to any one of features 1 to 3, further including:

forming a second layer at a side surface of the first metal layer facing the second metal layer,

the second layer substantially not including aluminum,

the processing of the upper surface of the semiconductor layer by wet etching being performed after the forming of the first and second layers.

Feature 5

The method according to any one of features 1 to 4, in which

the processing by wet etching includes using a chemical liquid including fluorine.

Feature 6

The method according to any one of features 1 to 5, further including:

forming a third metal layer at a lower surface of the semiconductor layer after the forming of the semi-insulating layer.

Feature 7

The method according to any one of features 1 to 6, in which

the semiconductor layer includes:

a first semiconductor region of a first conductivity type;

a second semiconductor region located between the first semiconductor region and the first metal layer, the second semiconductor region being of a second conductivity type; and

a third semiconductor region located around the second semiconductor region along the first plane, the third semiconductor region being of the second conductivity type, and

the third semiconductor region is electrically connected with the semi-insulating layer.

Feature 8

The method according to feature 7, in which

the semiconductor layer further includes:

a fourth semiconductor region located on the second semiconductor region, the fourth semiconductor region being of the first conductivity type; and

a gate electrode facing the second semiconductor region via a gate insulating layer.

Feature 9

The method according to any one of features 1 to 8, in which

an electrical resistivity of the semi-insulating layer is greater than 1.0×10⁸ Ω⋅cm and less than 1.0×10¹³ Ω⋅cm.

Feature 10

The method according to any one of features 1 to 9, in which

the first layer includes at least one selected from the group consisting of tungsten, molybdenum, titanium nitride, silicon nitride, and tantalum nitride.

Feature 11

A semiconductor device, including:

a first electrode;

a semiconductor layer located on the first electrode;

a second electrode located on a part of the semiconductor layer;

a third electrode located around the second electrode along a first plane on another part of the semiconductor layer, the first plane being perpendicular to a first direction from the first electrode toward the semiconductor layer, the third electrode including aluminum;

a semi-insulating layer contacting an upper surface of the semiconductor layer and being electrically connected with the second and third electrodes; and

a first layer located between the semi-insulating layer and a side surface of the third electrode, the first layer being conductive and substantially not including aluminum.

Feature 12

The semiconductor device according to feature 11, in which

the first layer is conductive and is electrically connected with the semi-insulating layer.

Feature 13

The semiconductor device according to feature 12, in which

the first layer also is located at an upper surface of the third electrode.

Feature 14

The semiconductor device according to feature 11, further including:

a second layer located at a side surface of the second electrode facing the third electrode,

the second layer substantially not including aluminum.

Feature 15

The semiconductor device according to any one of features 11 to 14, in which

the semiconductor layer includes:

a first semiconductor region of a first conductivity type;

a second semiconductor region located between the first semiconductor region and the first metal layer, the second semiconductor region being of a second conductivity type; and

a third semiconductor region located around the second semiconductor region along the first plane, the third semiconductor region being of the second conductivity type, and

the third semiconductor region is electrically connected with the semi-insulating layer.

Feature 16

The semiconductor device according to feature 15, in which

the semiconductor layer further includes:

a fourth semiconductor region located on the second semiconductor region, the fourth semiconductor region being of the first conductivity type; and

a gate electrode facing the second semiconductor region via a gate insulating layer.

Feature 17

The semiconductor device according to any one of features 11 to 16, in which

an electrical resistivity of the semi-insulating layer is greater than 1.0×10⁸ Ω⋅cm and less than 1.0×10¹³ Ω⋅cm.

Feature 18

The method according to any one of features 11 to 17, in which

the first layer includes at least one selected from the group consisting of tungsten, molybdenum, titanium nitride, silicon nitride, and tantalum nitride.

According to the embodiments above, a semiconductor device and a method for manufacturing a semiconductor device are provided in which short-circuits can be suppressed.

In the embodiments above, the relative levels of the impurity concentrations between the semiconductor regions can be confirmed using, for example, a scanning capacitance microscope (SCM). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured, for example, using secondary ion mass spectrometry (SIMS).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A method for manufacturing a semiconductor device, the method comprising:
preparing a structure body, the structure body including
a semiconductor layer,
a first metal layer located on a part of the semiconductor layer, and
a second metal layer located around the first metal layer along a first plane on another part of the semiconductor layer, the first plane being perpendicular to a first direction from the semiconductor layer toward the first metal layer, the second metal layer including aluminum;
forming a first layer at a side surface of the second metal layer facing the first metal layer, the first layer substantially not including aluminum;
processing an upper surface of the semiconductor layer by wet etching; and
forming a semi-insulating layer in contact with the upper surface of the semiconductor layer, the semi-insulating layer being electrically connected with the first and second metal layers.

2. The method according to claim 1, wherein
the first layer is conductive and is electrically connected with the semi-insulating layer.

3. The method according to claim 2, wherein
the first layer also is formed at the upper surface of the second metal layer.

4. The method according to claim 1, further comprising:
forming a second layer at a side surface of the first metal layer facing the second metal layer,
the second layer substantially not including aluminum,
the processing of the upper surface of the semiconductor layer by wet etching being performed after the forming of the first and second layers.

5. The method according to claim 1, wherein
the processing by wet etching includes using a chemical liquid including fluorine.

6. The method according to claim 1, further comprising:
forming a third metal layer at a lower surface of the semiconductor layer after the forming of the semi-insulating layer.

7. The method according to claim 1, wherein
the semiconductor layer includes:
a first semiconductor region of a first conductivity type;
a second semiconductor region located between the first semiconductor region and the first metal layer, the second semiconductor region being of a second conductivity type; and
a third semiconductor region located around the second semiconductor region along the first plane, the third semiconductor region being of the second conductivity type, and
the third semiconductor region is electrically connected with the semi-insulating layer.

8. The method according to claim 7, wherein
the semiconductor layer further includes:
a fourth semiconductor region located on the second semiconductor region, the fourth semiconductor region being of the first conductivity type; and
a gate electrode facing the second semiconductor region via a gate insulating layer.

9. The method according to claim 1, wherein
an electrical resistivity of the semi-insulating layer is greater than 1.0×10⁸ Ω⋅cm and less than 1.0×10¹³9Ω⋅cm.

10. The method according to claim 1, wherein
the first layer includes at least one selected from the group consisting of tungsten, molybdenum, titanium nitride, silicon nitride, and tantalum nitride.

11. A semiconductor device, comprising:
a first electrode;
a semiconductor layer located on the first electrode;
a second electrode located on a part of the semiconductor layer;
a third electrode located around the second electrode along a first plane on another part of the semiconductor layer, the first plane being perpendicular to a first direction from the first electrode toward the semiconductor layer, the third electrode including aluminum;
a semi-insulating layer contacting an upper surface of the semiconductor layer and being electrically connected with the second and third electrodes; and
a first layer located between the semi-insulating layer and a side surface of the third electrode, the first layer being conductive and substantially not including aluminum.

12. The semiconductor device according to claim 11, wherein
the first layer is conductive and is electrically connected with the semi-insulating layer.

13. The semiconductor device according to claim 12, wherein
the first layer also is located at an upper surface of the third electrode.

14. The semiconductor device according to claim 11, further comprising:
a second layer located at a side surface of the second electrode facing the third electrode,
the second layer substantially not including aluminum.

15. The semiconductor device according to claim 11, wherein
the semiconductor layer includes:
a first semiconductor region of a first conductivity type;
a second semiconductor region located between the first semiconductor region and the first metal layer, the second semiconductor region being of a second conductivity type; and
a third semiconductor region located around the second semiconductor region along the first plane, the third semiconductor region being of the second conductivity type, and
the third semiconductor region is electrically connected with the semi-insulating layer.

16. The semiconductor device according to claim 15, wherein
the semiconductor layer further includes:
a fourth semiconductor region located on the second semiconductor region, the fourth semiconductor region being of the first conductivity type; and
a gate electrode facing the second semiconductor region via a gate insulating layer.

17. The semiconductor device according to claim 11, wherein
an electrical resistivity of the semi-insulating layer is greater than 1.0×10⁸ Ω⋅cm and less than 1.0×10¹³17Ω⋅cm.

18. The semiconductor device according to claim 11, wherein
the first layer includes at least one selected from the group consisting of tungsten, molybdenum, titanium nitride, silicon nitride, and tantalum nitride.
